(19) United States
(12) Patent Application Publication
(10) Pub. No.: US 2026/0214866 A1
(43) Pub. Date: Jul. 23, 2026

(54) Control Device and Method for Cooling Control Units

(71) Applicant: BAYERISCHE MOTOREN WERKE AKTIENGESELLSCHAFT, München (DE)

(72) Inventor: Daniel MATLOK, Stein (DE)

(21) Appl. No.: 19/157,783

(22) PCT Filed: Mar. 27, 2024
(86) PCT No.: PCT/EP2024/058200

§ 371 Date: Aug. 19, 2025

(30) Foreign Application Priority Data
Apr. 27, 2023 (DE) 10 2023 110 946.4

(51) Int. Cl. H05K 7/20; B60W 50/023

(52) U.S. Cl. CPC H05K 7/20881; H05K 7/20327; B60W 50/023

(57) ABSTRACT

The invention relates to a control device for a motor vehicle in which at least two mutually redundant control units are jointly housed. A cooling means cools the control units during a normal operation. An emergency cooling means cools the cooling means during an emergency operation in which the cooling means alone cannot adequately cool the control units.

### BACKGROUND AND SUMMARY

The invention relates to a control device, in particular for a motor vehicle, and to a method for cooling at least two mutually redundant control units.

For highly automated or autonomous driving functions where a driver is unavailable to take over the task of driving in the event of a fault, two separate control units are currently required in order to bring a motor vehicle to a safe state, for example to reliably stop the motor vehicle at the side of the road or to enable the driver to safely take over a driving task, even in the event of one control unit failing, by means of the second control unit that is independent of the first control unit. In order to ensure the independence between the control units required for this such that a technical defect or fault does not result in both control units failing (this relates to failures due to common external causes, failures due to functional dependencies of the components and failures due to common causes inherent in the control units), it is possible, for example, to use a separate power supply for each control unit and separate cooling circuits or heat sinks for the control units, different installation spaces, different configurations and different data systems or bus systems in order to prevent such an event.

DE 102 43 713 B4 discloses a control unit assembly having multiple control units interconnected via a first data bus, the control units controlling components of a means of transport and exchanging information with one another via the first data bus. Control units of redundant design with respect to a control function are provided.

Furthermore, DE 10 2019 212 370 A1 discloses a cooling device for an electrical control unit on board a motor vehicle.

The object of the present invention is to provide a solution that enables particularly compact integration of two redundant control units.

This object is achieved by one or more features of the various embodiments described herein. Features, advantages and possible refinements that are presented in the context of the description of any described embodiment should be considered at least analogously as features, advantages and possible refinements of the respective subject matter of other described embodiment and of any possible combination of the subject matter of the described embodiments.

The invention relates to a control device, in particular for a motor vehicle, in particular for a car, in particular for a passenger car. As an alternative, the control device may be used in aerospace, in a power plant or in industry. The control device comprises at least two mutually redundant control units. The control units are each configured to execute a driver assistance function or an automated or autonomous vehicle guidance function and to take over or to support the driving task by means of activated actuators. The driver assistance function can be used to assist a driver of the motor vehicle in controlling the motor vehicle. The redundancy of the control units is to be understood as meaning that the two control units can control the same automated or autonomous driving functions independently of one another. An automated or autonomous driving function can thus be controlled by means of a first of the control units or by means of the second control unit. The fact that two control units are provided means that a fallback level is provided in the event that one of the control units fails. It is thus ensured that, even in the event of a failure of one of the control units, the driver assistance function or automated or autonomous driving function can be reliably controlled by means of the other control unit. The control device comprises a cooling means that is configured to cool the control units in normal operation. The control device furthermore comprises an emergency cooling means that is configured to cool the cooling means in emergency operation in which the cooling means alone cannot adequately cool the control units. In particular, the cooling means and the emergency cooling means differ in terms of their construction. In particular, the cooling means and the emergency cooling means can differ from one another in terms of their cooling power and/or in terms of their size. Provision may be made for the cooling means to be connected to a cooling circuit of the motor vehicle. The emergency cooling means is in this case independent of the cooling circuit to which the cooling means is connected. The emergency cooling means is activated in particular only during emergency operation. In normal operation, the cooling means or the control units are not cooled by means of the emergency cooling means. For a particularly compact design of the control device, the cooling means may be part of the housing. This means that the cooling means constitutes a housing wall of the housing. The emergency cooling means can also be designed such that it is attached to or integrated into the housing or the cooling means as a replaceable element. The control units may be in contact with the cooling means in order to cool the control units. The control units are held in a joint volume that is enclosed by the housing. In other words, the control device comprises two mutually redundant control units that are arranged in a joint housing. In normal operation, both control units are cooled by means of the joint cooling means. In normal operation in which the joint cooling means cannot adequately cool the control units, the emergency cooling means is activated, which in turn cools the cooling means. The control device enables a particularly compact arrangement of the control units since these are arranged in the joint housing. Furthermore, sufficient cooling of the control units is ensured in the cooling device since the control units are cooled by means of the emergency cooling means in the event of the cooling means failing.

In one possible development, provision is made for the emergency cooling means to be in the form of an evaporation cooling means or a latent heat store or a thermochemical heat store or a refrigerating machine. An evaporation cooling means uses the principle of being able to cool a liquid by pumping out the vapor via the liquid. In particular, the emergency cooling means may be in the form of a boiling cooling means. Boiling cooling is a form of evaporation cooling in which the cooling liquid systematically heats up to boiling point. Boiling cooling is more effective than cooling via heat conduction, convection or heat dissipation alone. A latent heat store is also referred to as a phase-change-material store (PCM store). This is a specific type of refrigerant storage means in which a phase change of the aggregate state of a substrate is used. Latent heat stores can take up very large amounts of heat in a small temperature range around the phase change so that, in this specific temperature range, cooling can be effected with great power. Thermochemical heat stores store heat by way of an endothermic reaction and output it again by way of an exothermic reaction. This means that heat can be taken up by the cooling means in the course of the endothermic reaction by means of the thermochemical heat store, as a result of which the cooling means can be cooled in emergency operation. Thermochemical heat stores have a particularly high storage density, which means that the thermochemical heat store has a particularly great cooling capacity with a particularly small size.

A refrigerating machine often uses a thermodynamic cycle in which heat that is to be dissipated is taken up by a working fluid, which in turn is cooled by a combined heat and power machine. In the cycle, exergy in the form of electricity or thermal heat is supplied. Exergy refers to the proportion of the total energy of a system or mass flow that can perform work when it is brought into thermodynamic (thermal, mechanical and chemical) equilibrium with the surroundings thereof. The exergy taken up and the heat from the heat transition upon cooling are dissipated to the surroundings at a relatively high temperature level. The refrigerating machine may be in particular a Stirling engine or a pulse tube refrigerator or an absorption refrigerating machine, in particular a diffusion absorption refrigerating machine, or an adsorption refrigerating machine or a device configured to cool using magnetic cooling or a device configured to cool using the thermoelectric effect. In the Stirling engine, a gas is heated by externally supplied energy in a chamber closed by a piston and referred to as a cylinder, and is expanded, into another chamber also closed by a piston, also referred to as a cylinder, is cooled and is compressed. The gas moves between these two chambers and in the process changes in temperature and pressure. The Stirling engine operates using a cycle referred to as a Stirling cycle. A pulse tube refrigerator is a refrigerating machine whose functional principle corresponds approximately to a Stirling engine but which does not require any mechanically moving parts. As a result, very compact cooling heads are possible and a minimum temperature reached is not limited by mechanical friction heat of these parts.

The device, which is configured to cool using magnetic cooling, can cool, in particular, by adiabatic demagnetization. This cooling method is based on the magnetic properties of particular materials. When magnetized, some materials release heat. These materials are referred to as magnetocaloric substances. In magnetic cooling, the material is introduced into a magnetic field, whereupon it heats up. The heat is in this case usually dissipated by means of a cooling liquid. The material that is brought back to ambient temperature then leaves the magnetic field and is demagnetized in the region that is to be cooled.

The device, which is configured to cool using the thermoelectric effect, may comprise, in particular, a Peltier element. The Peltier element is electrically operated and manages without a coolant. A Peltier element is an electrothermal transducer that produces a temperature difference when a current flows through it or produces a flow of current in the event of a temperature difference on the basis of the Peltier effect.

An absorption refrigerating machine operates using a working fluid consisting of two components, a solvent and the coolant. The coolant must be fully soluble in the solvent. The absorption refrigerating machine is a refrigerating machine in which, in contrast to the compression refrigerating machine, compression takes place by way of a temperature-influenced dissolving of the coolant. The absorption refrigerating machine is thus also referred to as a thermal compressor. The coolant is absorbed in a second substance at a low temperature and desorbed at higher temperatures in a solvent circuit. In this process, the temperature dependency of the physical solubility of two substances is used. The diffusion absorption refrigerating machine is a modification of the absorption refrigerating machine. An adsorption refrigerating machine is used to produce cold and is based on the reversible adsorption of an active substance in a host structure. The functional sequence is the same as in an absorption refrigerating machine, the difference being that the active substance is not adsorbed on a liquid but a solid. The active substance takes up energy from the surroundings and evaporates it. The surroundings cool down in this case due to the evaporation chill. The now gaseous active substance is taken up by the porous host structure and condenses in the pores thereof. The host structure heats up due to condensation enthalpy.

In particular, the emergency cooling means is a cooling apparatus that is independent of the cooling circuit of the cooling means. The respective described refinements of the emergency cooling means enable stable and reliable cooling of the cooling means in emergency operation in order to ensure that at least one of the control units, in particular both control units, are adequately cooled in emergency operation.

In another possible refinement, provision is made for the emergency cooling means to comprise a cooling surface from which heat is drawn in emergency operation. This cooling surface is in contact with the cooling means, as a result of which the cooling means is cooled by means of the emergency cooling means in emergency operation. Heat is thus drawn by means of the emergency cooling means from the cooling means by way of the cooling surface of the emergency cooling means in emergency operation in order to cool the cooling means. In particular, the emergency cooling means is able to be replaced reversibly on the cooling means. If, for example, the emergency cooling means has been used and has cooled the cooling means in emergency operation, it may then be that the emergency cooling means needs to be regenerated. For this regeneration of the emergency cooling means, the emergency cooling means can be removed from the cooling means and, for example, an already regenerated emergency cooling means can be attached to the cooling means, in particular can be placed on the cooling means by way of the cooling surface thereof. It is thus possible to restore the control device particularly easily after the emergency cooling means has been used to cool the cooling means.

In another possible refinement, provision is made for the cooling means to comprise multiple cooling ribs by means of which the cooling means can be air-cooled in normal operation. As an alternative or in addition, provision is made for the cooling means to comprise one or more cooling lines by way of which a cooling fluid of the cooling circuit is guided in normal operation. The cooling means can therefore be cooled in normal operation by means of air and/or by means of the cooling fluid. The cooling means can be cooled particularly uniformly thanks to the cooling ribs or the cooling lines.

In another possible refinement, provision is made for the emergency cooling means to be configured to keep a temperature of at least one of the control units below a predefined limit temperature at least for a predefined time interval. In this case, the limit temperature can be selected in particular in such a way that, as long as the temperature of the control units is below the limit temperature, a risk of damage to the control units is particularly low. It can thus be ensured that at least one of the control units is kept running sufficiently long by cooling the cooling means in emergency operation by means of the emergency cooling means such that the motor vehicle can be brought to a safe state, such as safely stopping on the side of the road or safely handing over the driving task to the driver. It is thus determined how long is usually required to bring the motor vehicle to the safe state in an emergency situation. The emergency cooling means is then designed in such a way that it can be used to cool the cooling means in such a way that the temperature of the control units can be kept below the limit temperature at least for this required time. A collision risk of the motor vehicle in the event of the cooling means failing due to a failure of both control units can thus be kept particularly low.

In another possible refinement, provision is made for the emergency cooling means to have a coolant tank in which a coolant in liquid form is held. The coolant tank is closed by a closure, which is opened in emergency operation. This allows coolant that is evaporated by the cooling means with absorption of heat to leave the coolant tank via the closure. Evaporation cooling is thus used to cool the cooling means by means of the emergency cooling means. Opening the closure reduces pressure in the coolant tank, as a result of which the coolant in the coolant tank, which is stored in particular under pressure, is evaporated. As a result of the evaporation of the coolant, the evaporating coolant draws heat from its surroundings, which can achieve a cooling effect. The cooling means can thus be cooled particularly easily and quickly by means of the emergency cooling means through the opening of the closure of the emergency cooling means.

In this context, in one development, provision may be made for the closure to be configured to uncover the opening when at least one of the control units reaches a trigger temperature for opening the closure that is predefined for the respective control unit. As a result of the fact that the at least one control unit can no longer be cooled by means of the cooling means, the at least one control unit heats up and the temperature thereof approaches the trigger temperature. Provision is thus made for the reaching of the trigger temperature at the at least one control unit to trigger the closure uncovering the opening and consequently the emergency cooling means cooling the at least one control unit, in particular both control units, by means of the cooling means. Reliable activation of the emergency cooling means is thus ensured as soon as the at least one control unit has reached the predefined trigger temperature. The same trigger temperature may be predefined for both control units, or an individual trigger temperature may be predefined for each of the control units. In this case, it must be ensured that the closure uncovers the opening as soon as one of the control units reaches the trigger temperature predefined for this control unit.

In this context, in another refinement, provision may be made for the closure to be designed in such a way that a melting temperature for a material of the closure is reached in the closure when at least one of the control units reaches the trigger temperature for opening the closure that is predefined for the respective control unit. The heat is transferred from the heated control unit via the cooling means to the emergency cooling means and thus also to the closure of the emergency cooling means via heat conduction. In particular, the melting temperature of the closure is selected in such a way that it melts when one of the control units has reached the trigger temperature. It is thus possible to back-calculate, by means of the respective heat conduction in the cooling means and the emergency cooling means, what melting temperature the closure may have at most in order to melt at the latest when the at least one control unit has reached the trigger temperature. As soon as the at least one control unit has reached the trigger temperature, the melting temperature of the closure has occurred in the closure such that the closure melts and the opening is uncovered. This triggers the cooling function of the emergency cooling means. A material having the desired melting temperature is thus selected for the closure. Triggering the uncovering of the opening of the coolant tank by the melting temperature of the closure being reached can ensure that the emergency cooling means is activated reliably as soon as the at least one control unit has reached the trigger temperature. A risk of the control unit heating up to the predefined limit temperature that is above the trigger temperature for the operation of the control unit can thus be kept particularly low. It is thus possible to ensure reliable operation of the motor vehicle even if the cooling means fails.

In an alternative refinement, provision may be made for a trigger apparatus to be provided, which is configured to trigger the closure being electrically melted and/or the closure being opened by means of a pyrotechnic charge and/or the closure being opened piezoelectrically and/or the closure being opened mechanically, in particular by means of an actuating drive, as soon as it is determined that the predefined trigger temperature has been reached. For example, a sensor apparatus can be provided, by means of which the temperature of the control units is checked. If the sensor apparatus thus ascertains that at least one of the control units has reached the trigger temperature predefined for this control unit, the opening of the closure is activated by means of the trigger apparatus. A heating element, for example, can be provided to electrically melt the closure. As soon as it is identified that the predefined trigger temperature of the at least one control unit has been reached, the trigger apparatus can trigger an explosion of the pyrotechnic charge, as a result of which the closure at least partly comes out of the opening and so the opening is opened. For the piezoelectric opening of the closure, the trigger apparatus can trigger the application of a current or the interruption of a circuit on a piezoelectric element, which closes the opening as a closure. The piezo element uncovers the opening through the application or the interruption of the flow of electric current through the piezo element. The actuating drive can be driven by an electric motor. The actuating drive can be used to move a mechanical closure element of the closure between an uncovered position that uncovers the opening and a closed position that closes the opening. In this refinement, provision is thus made for the uncovering of the opening to be actively controlled.

The invention furthermore relates to a method for cooling at least two mutually redundant control units that are accommodated in a joint housing. The control units may be used in a motor vehicle, in aerospace, in a power plant or in industry. In the method, provision is made for, in normal operation, the control units to be cooled by means of a cooling means and, in emergency operation in which the cooling means alone cannot adequately cool the control units, the cooling means to be cooled by means of the emergency cooling means. In the context of the method, the control units of the control units described in connection with the control device according to the invention are thus cooled.

Further features of the invention may emerge from the claims, the figures and the description of the figures. The features and combinations of features mentioned above in the description and the features and combinations of features shown below in the description of the figures and/or in the figures alone can be used not only in the respectively stated combination but also in other combinations or alone, without departing from the scope of the invention.

### BRIEF DESCRIPTION OF THE DRAWINGS

FIG. 1 shows a schematic structure of a control device for a motor vehicle;

FIG. 2 shows a schematic sectional illustration of the control device in normal operation; and

FIG. 3 shows a sectional schematic view of the control device in emergency operation.

### DETAILED DESCRIPTION OF THE DRAWINGS

Identical and functionally identical elements are provided with the same reference signs in the figures.

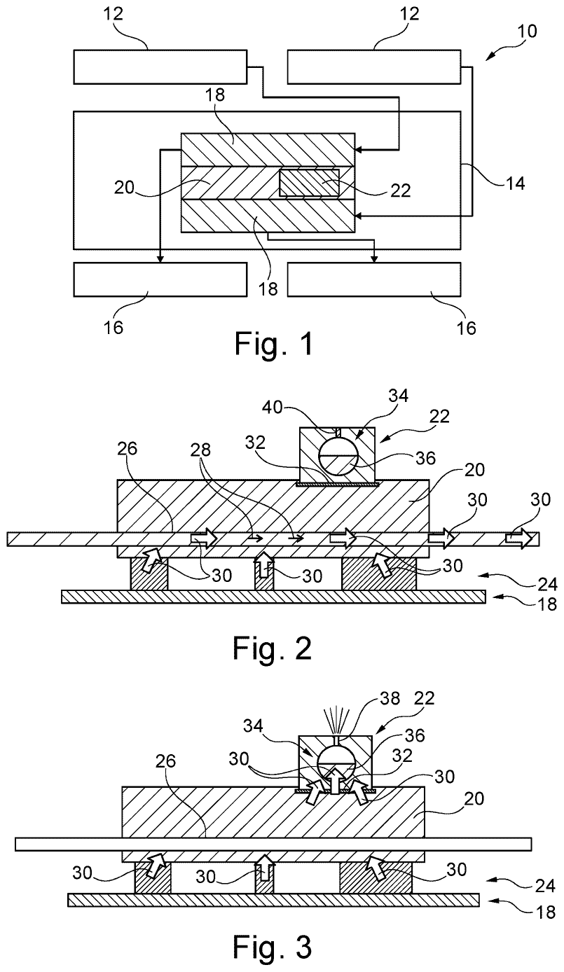

FIG. 1 illustrates a control assembly 10 for a motor vehicle. The control assembly 10 is configured to execute a driver assistance function or automated or autonomous driving function of the motor vehicle. The control assembly 10 comprises mutually redundant sensors 12, a control device 14 and mutually redundant actuators 16. The control device 14 comprises two control units 18 that are formed so as to be mutually redundant. This means that the control units 18 are configured to control the same driver assistance function independently of one another. The respective control units 18 are hardware by means of which software is executed and which may comprise in particular a printed circuit board 24. A first of the control units 18 receives sensor data from first sensors 12 and controls first actuators 16. The second control unit 18 receives sensor data from the second sensors 12 and controls the second actuators 16. The control units 18 are accommodated in a joint housing.

The control device 14 furthermore comprises a cooling means 20 that is configured to cool both control units 18. The cooling means 20 may be in particular part of the housing in which the control units 18 are accommodated. The cooling means 20 may have cooling ribs by way of which heat can be dissipated to ambient air by the cooling means 20 via passive convection cooling. As an alternative or in addition, the cooling means 20 can have multiple cooling lines and thus a pipe system that can be fluidically connected to a cooling circuit of the motor vehicle. Cooling fluid, in particular cooling water, can flow in these cooling lines, by means of which cooling fluid heat 30 can be taken up by the cooling means 20, which cools the cooling means 20. The control units 18 are cooled by means of the cooling means 20 in normal operation.

In order to ensure at least temporarily adequate cooling of the control units 18 in the event of the cooling means 20 failing, an emergency cooling means 22 is provided. The emergency cooling means 22 is configured, in emergency operation in which the cooling means 20 alone cannot adequately cool the control units 18, to cool the cooling means 20, as a result of which the control units 18 are cooled by means of the cooled cooling means 20. The emergency cooling means 22 is configured to keep a temperature of at least one of the control units 18 below a predefined limit temperature at least for a predefined time interval, as a result of which the motor vehicle can be brought to a safe state despite the failure of the cooling means 20.

The emergency cooling means 22 may be in the form of an evaporation cooling means. The emergency cooling means 22 may alternatively be configured, as a latent heat store by means of a phase change of a material, to take up heat 30 from the surroundings and as a result cool the cooling means 20. As an alternative, the emergency cooling means 22 may be in the form of a thermochemical heat store. Furthermore, as an alternative, the emergency cooling means 22 may be in the form of a refrigerating machine, in particular in the form of a Stirling engine or a pulse tube refrigerator or an absorption refrigerating machine, in particular a diffusion absorption refrigerating machine, or an adsorption refrigerating machine or a device configured to cool using magnetic cooling or a device configured to cool using the thermoelectric effect.

FIGS. 2 and 3 show a section of the control device 14. In these figures, the control device 14 is shown in normal operation in FIG. 2 and in emergency operation in FIG. 3. FIGS. 2 and 3 schematically illustrate one of the control units 18 in the form of a printed circuit board 24. This printed circuit board 24 is in contact with the cooling means 20, which in the present case is in the form of a heat exchanger. The cooling means 20 here comprises at least one cooling line 26 through which a cooling fluid 28 of the cooling circuit flows in normal operation. The cooling fluid 28 flowing in the cooling line 26 is indicated by means of respective arrows. In FIG. 2, it can be seen that heat 30 is output from the printed circuit board 24 to the cooling means 20 and from the cooling means 20 to the cooling fluid 28 in normal operation. The cooling fluid 28 is used to transport the heat 30 away from the cooling means 20 via the cooling circuit. In the emergency operation shown in FIG. 3, no cooling fluid 28 flows through the cooling line 26 of the cooling means 20. Heat 30 is thus not drawn from the cooling means 20 by means of the cooling fluid 28 in emergency operation. Adequate cooling of the printed circuit board 24 is thus not possible by means of the cooling means 20 alone in emergency operation. If the cooling means 20 were not cooled by means of the emergency cooling means 22 in emergency operation, then the printed circuit board 24 could overheat. The emergency cooling means 22 is therefore provided to prevent this overheating of the printed circuit board 24. The emergency cooling means 22 is in contact with the cooling means 20 in this case. The emergency cooling means 22 comprises a cooling surface 32 from which heat 30 is drawn in emergency operation. This cooling surface 32 is in contact with the cooling means 20, as a result of which the cooling means 20 is cooled by means of the emergency cooling means 22 in emergency operation. The emergency cooling means 22 may be screwed to the cooling means 20 or may be fully integrated into the cooling means 20. It must be ensured that heat is adequately transferred from the cooling means 20 to the emergency cooling means 22.

FIGS. 2 and 3 show a refinement of the emergency cooling means 22 in which the emergency cooling means 22 comprises a coolant tank 34, in which a coolant 36 in liquid form is held. This coolant 36 is in particular stored under pressure in the coolant tank 34. An opening 38 in the coolant tank 34 is closed by a closure 40 in normal operation. In emergency operation, the opening 38 is open and thus uncovered by the closure 40, as a result of which evaporated coolant 36 can leave the coolant tank 34 via the opening 38 due to a fall in pressure. The coolant 36 is in particular liquid gas. After the opening 38 has been uncovered, the pressure in the coolant tank 34 decreases, as a result of which at least some of the liquid coolant 36 evaporates. Heat energy is drawn from the emergency cooling means 22 due to the phase transition of the coolant 36 from liquid to gaseous and due to the gas leaving the emergency cooling means 22 via the opening 38. This is the principle of evaporative cooling. As a result, the coolant 36 that is currently still liquid in the coolant tank 34 cools down. This liquid portion of the coolant 36 takes up heat 30 from the cooling surface 32, as a result of which the cooling means 20 is cooled in turn by means of the cooled cooling surface 32. Sources of heat on the printed circuit board 24 can be cooled by the cooling means 20. These sources of heat on the printed circuit board 24 may be a processor or a memory or power components, for example.

If the coolant 36 has fully transitioned from the liquid to the gaseous phase, then the cooling power of the emergency cooling means 22 is exhausted. In particular, the cooling power or the supply of coolant 36 of the emergency cooling means 22 is measured so that the system or the motor vehicle has reached a safe state, in particular has stopped, up to the point when the cooling power of the emergency cooling means 22 is exhausted. For example, the emergency operation may be required as a result of the cooling fluid 28 being missing or not flowing in the cooling line 26 or incorrectly having too high a temperature that is insufficient for cooling.

The closure 40 is configured in particular to uncover the opening 38 when at least one of the control units 18 has reached a trigger temperature for opening the closure 40 that is predefined for the respective control unit 18. This trigger temperature is in particular below the predefined limit temperature below which the temperature of the control units 18 is to be kept by means of the emergency cooling means 22 at least for the predefined time interval in order to ensure that the motor vehicle can be transferred to the safe state. In order to ensure that the closure 40 uncovers the opening 38 when at least one of the control units 18 has reached the trigger temperature that is predefined for this control unit 18, provision may be made for the closure 40 to be designed in such a way that a melting temperature for a material of the closure 40 is reached in the closure 40 when at least one of the control units 18 reaches the trigger temperature for opening the closure 40 that is predefined for the respective control unit 18. If one of the control units 18 has thus heated up to the trigger temperature that is predefined for this control unit 18, then the closure 40 has heated up to the melting temperature by means of heat conduction from the control unit 18 via the cooling means 20 to the emergency cooling means 22, as a result of which at least regions of the closure 40 melt and the opening 38 is therefore uncovered.

As an alternative, a temperature sensor can be used to determine that the trigger temperature has been reached in the at least one control unit 18. As a result of the fact that the at least one temperature sensor has determined that the trigger temperature provided for the at least one control unit 18 has occurred in this control unit 18, a trigger apparatus is used to trigger the uncovering of the opening 38 by the closure 40. In this case, the trigger apparatus can be used to trigger the closure 40 being electrically melted and/or the closure 40 being opened by means of a pyrotechnic charge, in particular being blasted off, and/or the closure 40 being opened piezoelectrically and/or the closure 40 being opened mechanically.

Integrating the two redundant control units 18 into the joint housing can result in cost advantages and installation space advantages. In this case, the two control units 18 divide the cooling means 20 on account of the joint housing. If cooling by the cooling means 20 fails, the problem that both redundant control units 18 could fail at the same time could arise without protection. The control device 14 described comprises the emergency cooling means 22, which makes it possible for the motor vehicle to be able to be brought to a safe state by one of the redundant control units 18 if the cooling means 20 fails. This ensures that, even in the event of complete failure of the cooling means 20, for example as a result of a sudden loss of cooling water or a failure of a cooling fan, adequate dissipation of heat from the control units 18 is ensured in order to guarantee safe operation of the motor vehicle until a safe vehicle state has been reached.

The emergency cooling functionality of the emergency cooling means 22 can be implemented by introducing a gas under pressure, ideally in liquid form, into a cavity, in the present case the coolant tank 34 of the emergency cooling means 22. This gas, which is used as coolant 36, is ideally non-combustible and environmentally friendly and is released to the environment in a manner controlled by the opening 38 in the event of a cooling failure of the cooling means 20. Meanwhile, the motor vehicle transfers the driving task to the driver or stops automatically, for example. The gas takes up a large amount of environmental heat upon expanding or upon phase change from liquid to gaseous, as a result of which this taking-up of heat is provided in the form of cooling power to the cooling means 20. It is thus possible to compensate for the cooling failure of the cooling means 20 for the required time until the motor vehicle has reached a safe state. Safety and availability requirements relate only to the mechanism for the controlled release of the gas and not an overall cooling system of the motor vehicle. After the cooling means 20 has been repaired, the emergency cooling means 22 can be exchanged in full or in part for a new or for a processed one in a workshop. To release the gas, the closure 40 can be thermally melted by the excess temperature of the at least one control unit 18, in particular the determined trigger temperature of the at least one control unit 18. In addition, it is possible to trigger diagnostics with reporting for a driving function. To release the gas, as an alternative, it is possible to trigger active electrical melting of the closure 40 to the coolant tank 34 on account of a measured excess temperature, in particular the determined trigger temperature of the at least one control unit 18. As an alternative, the release of the gas can be triggered by actively triggering or opening the closure 40 to the coolant tank 34 by means of a small pyrotechnic charge similar to a pyrotechnic fuse in high-voltage batteries or airbag systems on account of an excess temperature measurement at the control units 18 and thus the determination of the trigger temperature. Furthermore, as an alternative, the release of the gas can be triggered by piezoelectric triggering or opening of the closure 40 as a result of the trigger temperature being determined at the at least one control unit 18.

As an alternative method for cooling the cooling means 20 by means of the emergency cooling means 22, the emergency cooling means 22 may comprise a sorption store. This sorption store may comprise for example zeolite or silica gel or metal hydride and water as the substance pair. The sorption store is a thermochemical heat store.

Overall, the invention shows how a failure-resistant cooling apparatus comprising the cooling means 20 and the emergency cooling means 22 can be provided for respective redundant control units 18 of a motor vehicle.

### List of Reference Signs

10 Control assembly
12 Sensors
14 Control device
16 Actuators
18 Control unit
20 Cooling means
22 Emergency cooling means
24 Printed circuit board
26 Cooling line
28 Cooling fluid
30 Heat
32 Cooling surface
34 Coolant tank
36 Coolant
38 Opening
40 Closure

1-10. (canceled)

11. A control device for a motor vehicle, comprising:
at least two mutually redundant control units;
a housing that houses the control units;
a cooling means configured to cool the control units during normal operation; and
an emergency cooling means configured to cool the cooling means during an emergency operation where the cooling means alone cannot adequately cool the control units.

12. The control device of claim 11, wherein the emergency cooling means comprises:
an evaporation cooling means,
a latent heat store,
a thermochemical heat store, or
a refrigerating machine in the form of: a Stirling engine, a pulse tube refrigerator, an absorption refrigerating machine, a diffusion absorption refrigerating machine, an adsorption refrigerating machine, a device configured to cool using magnetic cooling, or a device configured to cool using the thermoelectric effect.

13. The control device of claim 11,
wherein the emergency cooling means comprises a cooling surface from which heat is drawn in emergency operation, and
wherein the cooling surface is in contact with the cooling means such that the cooling means is cooled by means of the emergency cooling means in emergency operation.

14. The control device of claim 11, wherein the cooling means comprises:
multiple cooling ribs via which the cooling means can be air-cooled in normal operation, and/or
one or more cooling lines via which a cooling fluid of a cooling circuit is guided in normal operation.

15. The control device of claim 11, wherein the emergency cooling means is configured to keep a temperature of at least one of the control units below a predefined limit temperature at least for a predefined time interval.

16. The control device of claim 11,
wherein the emergency cooling means comprises a coolant tank in which a coolant in liquid form is held,
wherein the coolant tank is closed by a closure configured to be opened in emergency operation to allow coolant that is evaporated by the cooling means with absorption of heat to leave the coolant tank via the closure.

17. The control device of claim 16, wherein the closure is configured to uncover the opening when at least one of the control units reaches a trigger temperature that is predefined for the respective control unit.

18. The control device of claim 17, wherein the closure is configured such that a melting temperature for a material of the closure is reached in the closure when at least one of the control units reaches the trigger temperature for opening the closure that is predefined for the respective control unit.

19. The control device of claim 17, wherein the closure is operably coupled to a trigger apparatus that triggers when the closure is: electrically melted, opened by means of a pyrotechnic charge, opened piezoelectrically, and/or opened mechanically via an actuating drive, as soon as it is determined that the predefined trigger temperature has been reached.

20. A method for cooling at least two mutually redundant control units that are accommodated in a joint housing, the method comprising:
cooling the control units by a cooling means in a normal operation; and
cooling the control units by an emergency cooling means in an emergency operation in which the cooling means alone cannot adequately cool the control units.
